(19) United States
(12) Patent Application Publication
(10) Pub. No.: US 2008/0273308 A1
(43) Pub. Date: Nov. 6, 2008

(54) MAGNETICALLY COUPLED COOLING BLOCK

(76) Inventors: Trevor A. Kells, Calgary (CA); Ryan Handy, Calgary (CA); Trentent Tye, Calgary (CA)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/742,592

(22) Filed: May 1, 2007

(51) Int. Cl. H05K 7/20

(52) U.S. Cl. 361/704

(57) ABSTRACT

A cooling mechanism comprises a first cooling block and a second cooling block. At least one of the first and second cooling blocks comprises a magnet to retain at least one of the blocks in place when cooling a heat-producing component.

### BACKGROUND

Cooling an electronic system becomes more challenging as the heat produced by the system's heat-producing components increases with evolving system designs. If a cooling system is attached to a heat-producing component, replacing the component or cooling system may require tools, time, and generally be difficult and cumbersome. Further, failure to properly secure the cooling mechanism to the heat-producing component may result in sub-optimal cooling.

### BRIEF DESCRIPTION OF THE DRAWINGS

For a detailed description of exemplary embodiments of the invention, reference will now be made to the accompanying drawings in which:

FIG. 1 shows a cooling block magnetically attached to a heat-producing component in accordance with various embodiments;

FIG. 2 shows a side view of the cooling mechanism of various embodiments;

FIG. 3 shows a top view of one of the cooling blocks comprising the cooling mechanism in accordance with an embodiment; and

FIG. 4 illustrates another retaining mechanism for the cooling mechanism.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection. The term “system” refers to a combination of two or more components. A system may comprise, for example, the combination of a server and a client communicatively coupled thereto, or a server alone, a client alone, or a subsystem within a computer.

### DETAILED DESCRIPTION

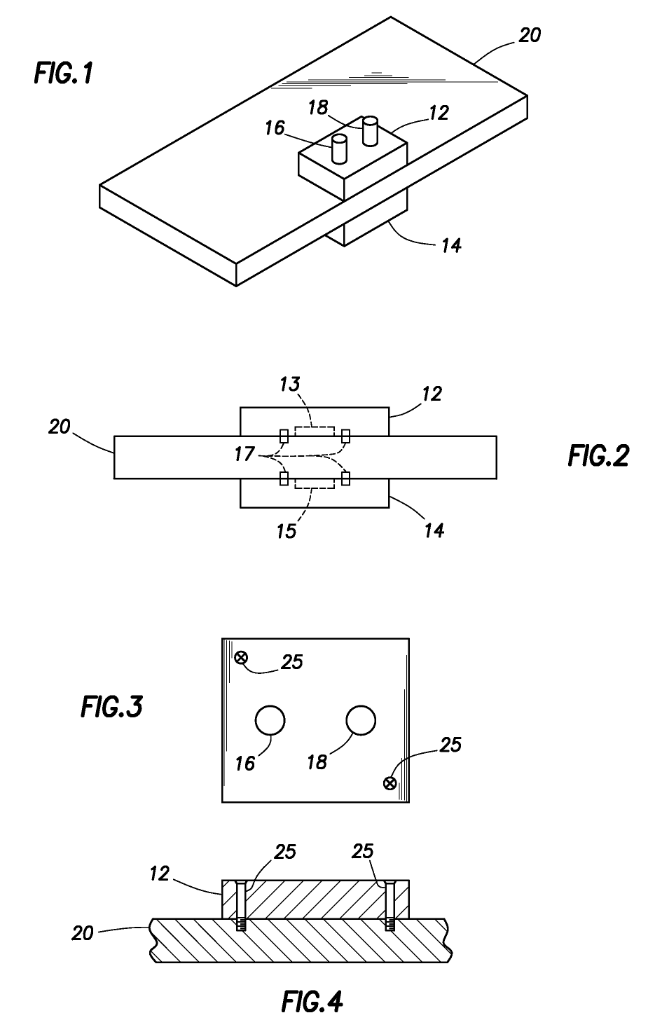

FIG. 1 shows an embodiment of a cooling mechanism magnetically coupled to a heat-producing component 20. The heat-producing component 20 can be any component such as a processor or graphics card. The cooling mechanism comprises at least two cooling blocks 12 and 14 provided on opposing sides of the heat-producing component 20. At least one of the cooling blocks 12, 14 comprises a magnet which magnetically couples to a corresponding magnetic surface (e.g., steel, ferrous material, etc.) of the heat-producing component. In some embodiments, each of the cooling blocks comprises a magnet. By providing magnets for coupling the cooling blocks 12, 14 to the heat-producing component 20, the cooling blocks 12, 14 and/or the heat-producing component can be readily removed and replaced without tools at least in some embodiments. Further, with magnetic coupling of the cooling blocks 12, 14 to the heat-producing component 20 helps to ensure satisfactory contact, and thus satisfactory heat transfer, between the heat-producing component 20 to the cooling blocks 12, 14.

In some embodiments, the magnet in each cooling block comprises a rare-earth magnet such as neodymium. In other embodiments, each cooling block's magnet comprises an electromagnet which receives current from a power supply in the system in which the heat-producing component resides. In some embodiments, the power is received from the heat-producing component itself.

In various embodiments, the cooling blocks 12 and 14 comprise water blocks. As such, at least one of the cooling blocks, and possibly both, comprise an inlet port 16 and an outlet port 18. A cold liquid flows into the inlet port 16, receives heat transferred to the liquid from the heat-producing component, and flows out the outlet port 18. The warm liquid is cooled and re-circulated back to the inlet port 16. In this manner, the heat-producing component 20 is cooled by the cooling mechanism.

FIG. 2 shows a side view of the heat-producing component 20 and the cooling mechanism. As can be seen, the heat-producing component 20 is sandwiched between the cooling blocks 12 and 14. Magnets 13 and 15 provided in cooling blocks 12 and 14, respectively, are also shown. One or more guide mechanisms 17 are provided to ensure that the cooling blocks 12 and 14 are retained on the heat-producing component in the correct location. In some embodiments, the guide mechanism for each cooling block 12, 14 comprises a guide pin that inserts into a corresponding slot on the heat-producing component. In other embodiments, the guide mechanism for each cooling block 12, 14 comprises a slot into which a guide pin provided on the heat-producing component is inserted.

In embodiments in which the magnets on the cooling blocks 12, 14 comprise electromagnets, power is not likely to be available to activate the magnets prior to the time the system is turned on. For example, during shipment of the system containing the heat-producing component 20, the magnets of the cooling blocks 12, 14 are not activated due to a lack of available electrical power. While the there would be no need to cool the heat-producing component during shipment, or at any time in which the system is powered off, the cooling blocks 12, 14 nevertheless should be retained in place on the heat-producing mechanism.

FIG. 3 shows a top view of one of the cooling blocks 12, 14. In addition to the inlet and outlet ports 16, 18, one or more retaining mechanisms 25 are provided to assist in coupling the cooling block to the heat-producing component 20. The retaining mechanisms 25 are particularly useful when the cooling blocks 12, 14 comprise electromagnets. The retaining mechanisms 25 comprise retaining mechanisms other than magnets. For example, the retaining mechanisms may comprise a bore in the cooling blocks into which a screw is received. As shown, in FIG. 4, the screw engages a threaded hole in the heat-producing component. In various embodiments, the adequacy of the retaining mechanism 25 is at least just enough to retain the cooling blocks 12, 14 on the heat-producing mechanism to avoid damaging any components during, for example, shipment.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A cooling mechanism, comprising:
a first cooling block; and
a second cooling block;
wherein at least one of said first and second cooling blocks comprises a magnet to retain at least one of the blocks in place when cooling a heat-producing component.

2. The cooling mechanism of claim 1 wherein at least one of the first and second cooling blocks comprises a water block.

3. The cooling mechanism of claim 1 wherein both of the first and second cooling blocks comprise water blocks.

4. The cooling mechanism of claim 1 further comprising at least one guide mechanism provided on at least one of said first and second cooling blocks.

5. The cooling mechanism of claim 4 wherein the at least one guide mechanism comprises a guide pin.

6. The cooling mechanism of claim 4 wherein the at least one guide mechanism comprises a slot for a guide pin.

7. The cooling mechanism of claim 1 wherein said magnet comprises a rare earth magnet.

8. The cooling mechanism of claim 1 wherein said magnet comprises an electromagnet.

9. The cooling mechanism of claim 8 further comprising an attachment mechanism other than a magnetic attachment mechanism to couple the first and second cooling blocks together when said electromagnet is not activated.

10. A system, comprising:
a heat-producing component; and
a cooling mechanism magnetically coupled to said heat-producing component.

11. The system of claim 10 the cooling mechanism comprises a water block.

12. The system of claim 10 wherein the cooling mechanism comprises at least two portions each magnetically coupled to opposing sides of the heat-producing component.

13. The system of claim 10 further comprising at least one guide mechanism provided cooling mechanism.

14. The system of claim 10 wherein said cooling mechanism comprises a rare earth magnet.

15. The system of claim 10 wherein said cooling mechanism comprises an electromagnet.

16. The system of claim 15 wherein the cooling mechanism comprises an attachment mechanism other than a magnetic attachment mechanism to couple the cooling mechanism to the heat-producing mechanism when said electromagnet is not activated.

17. The system of claim 10 wherein the heat-producing component comprises a component selected from a group consisting of a graphics card and a processor.

18. The system of claim 10 wherein the cooling mechanism comprises a water block.

19. A system, comprising:
first means for magnetically coupling to and for cooling a heat-producing component; and
second means for magnetically coupling to and for cooling the heat-producing component.

20. The cooling mechanism of claim 19 wherein the first and second means for magnetically coupling are for electromagnetically coupling.
